(19) United States
(12) Patent Application Publication
(10) Pub. No.: US 2019/0223297 A1
(43) Pub. Date: Jul. 18, 2019

(54) ALL-METAL SURFACE MOUNT FEMALE CONNECTOR AND CONNECTING STRUCTURE USING THE SAME

(71) Applicant: Xiamen GHGM Industrial Trade Co., Ltd., Xiamen (CN)

(72) Inventor: Bingshui Chen, Xiamen (CN)

(21) Appl. No.: 15/869,063

(22) Filed: Jan. 12, 2018

(51) Int. Cl. H05K 3/34; H01R 12/58; H01R 13/627; H01R 43/16; H01R 43/20; H01R 12/71; H01R 12/70; H01R 13/11

(52) U.S. Cl. CPC H05K 3/341; H01R 12/58; H01R 13/627; H01R 13/111; H01R 43/205; H01R 12/718; H01R 12/707; H01R 43/16

(57) ABSTRACT

An all-metal surface mount female connector has a SMT (surface mount technology) nozzle surface. The SMT nozzle surface is formed with an insertion hole for a wire to pass through the insertion hole from top to bottom. Two first opposing sides of the SMT nozzle surface are bent downward and approach each other to form an elastic clamp corresponding to the insertion hole for insertion of the wire. Two second opposing sides of the SMT nozzle surface are bent downward to form weld legs. The weld legs are electrically connected to a printed circuit board. The structure is simple, and the assembly is convenient. The female connector is suitable for the electrical connection of small-sized products.

### BACKGROUND OF THE INVENTION

### 1. Field of the Invention

The present invention relates to an all-metal surface mount female connector, and more particularly to an all-metal surface mount female connector for plugging a wire from top to bottom and a connecting structure using the same.

### 2. Description of the Prior Art

In the prior art, a wire is connected to a printed circuit board by welding. The connection operation is troublesome, and the connection is not firm.

A plug-in female connector is developed on the market. The female connector is mounted on a printed circuit board. The printed circuit board is formed with an insertion hole. A wire is inserted to pass through the insertion hole of the printed circuit board from bottom to top and then plugged to an elastic clamp of the female connector, thereby realizing the electrical connection between the printed circuit board and the wire. The operation of this electrical connection is simple, and the electrical connection is firm.

However, because the wire is plugged to the female connector from bottom to top, the printed circuit board must be provided with an insertion hole. When the female connector is assembled, the elastic clamp must be aligned with the insertion hole to achieve an effective connection between the wire and the elastic clamp. The operation for the assembly of the female connector is inconvenient. The required assembly area is large, the required operation space is large, and the printed circuit board is also large. The female connector is not suitable for the electrical connection of small-sized products.

Accordingly, the inventor of the present invention has devoted himself based on his many years of practical experiences to solve these problems.

### SUMMARY OF THE INVENTION

The primary object of the present invention is to provide an all-metal surface mount female connector for plugging a wire from top to bottom and a connecting structure using the same. The structure is simple, and the assembly is convenient. The female connector of the present invention is suitable for the electrical connection of small-sized products.

According to one aspect of the present invention, an all-metal surface mount female connector is provided. The all-metal surface mount female connector has a SMT (surface mount technology) nozzle surface. The SMT nozzle surface is formed with an insertion hole for a wire to pass through the insertion hole from top to bottom. Two first opposing sides of the SMT nozzle surface are bent downward and approach each other to form an elastic clamp corresponding to the insertion hole for insertion of the wire. Two second opposing sides of the SMT nozzle surface are bent downward to form weld legs. The weld legs are electrically connected to a printed circuit board.

Preferably, the two first opposing sides of the SMT nozzle surface are bent downward and inclined inwardly so that lower ends of the two first opposing sides approach each other to form the elastic clamp having oblique surfaces for guiding the wire to be inserted therein.

Preferably, lower ends of the two first opposing sides of the SMT nozzle surface are formed with a pair of clamping recesses corresponding to the insertion hole.

Preferably, the two second opposing sides of the SMT nozzle surface are bent downward and then horizontally bent outward to form the weld legs.

Preferably, lower ends of the two second opposing sides of the SMT nozzle surface are formed with the weld legs, respectively.

Preferably, the all-metal surface mount female connector is formed by stamping a metal sheet.

According to another aspect of the present invention, a connecting structure using the aforesaid all-metal surface mount female connector is provided. Wherein, the weld legs of the all-metal surface mount female connector are soldered on the printed circuit board. The wire passes through the insertion hole from top to bottom. The elastic clamp is configured to clamp the wire tightly to achieve an electrical connection between the wire and the printed circuit board.

The structure of the present invention is simple. When the female connector is to be assembled, the SMT nozzle surface is sucked by the SMT nozzle, and the female connector is arranged at a proper position of the printed circuit board, and then the weld legs are soldered on the printed circuit board to complete the assembly. The printed circuit board does not need to be provided with an insertion hole, so there is no need to align the elastic clamp with the insertion hole when assembled. The assembly operation is simpler and more convenient. The required assembly area is small, the required operation space is small, and the printed circuit board is also small. The female connector of the present invention is suitable for the electrical connection of small-sized products.

When in use, the wire passes through the insertion hole from top to bottom. The elastic clamp is configured to clamp the wire tightly, so that the electrical connection between the wire and the printed circuit board is achieved. The electrical connection way is simple, and the electrical connection is firm and stable.

### BRIEF DESCRIPTION OF THE DRAWINGS

FIG. 1 is a perspective top view of the present invention;

FIG. 2 is a perspective bottom view of the present invention;

FIG. 3 is an exploded view of the present invention when in use; and

FIG. 4 is a perspective view of the present invention when in use.

### DETAILED DESCRIPTION OF THE PREFERRED EMBODIMENTS

Embodiments of the present invention will now be described, by way of example only, with reference to the accompanying drawings.

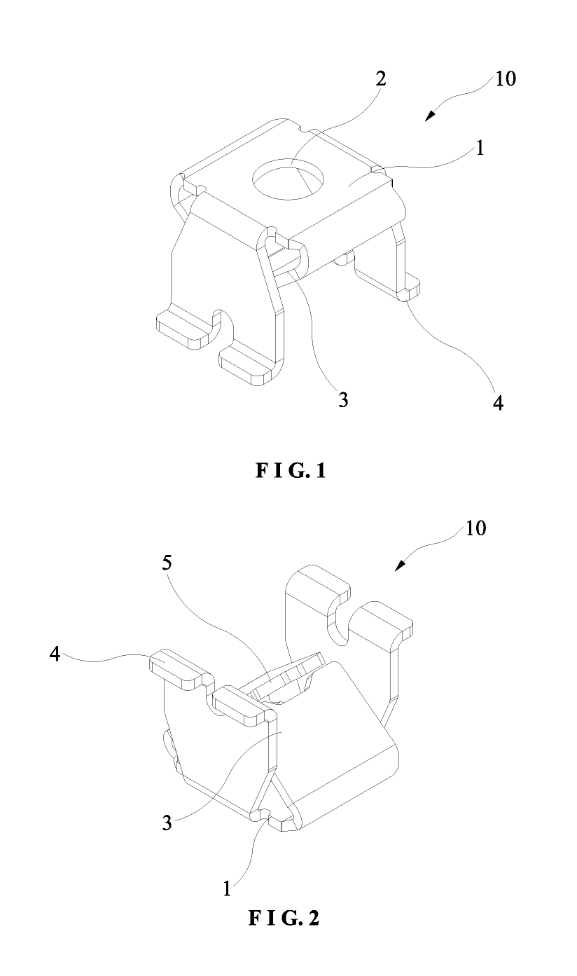

As shown in FIG. 1 to FIG. 4, the present invention discloses an all-metal surface mount female connector 10 for plugging a wire from top to bottom. The female connector 10 has a SMT (surface mount technology) nozzle surface 1. The SMT nozzle surface 1 is formed with an insertion hole 2 for a wire to pass through the insertion hole 2 from top to bottom. The insertion hole 2 is configured for a wire 20 to be inserted from top to bottom. Two first opposing sides of the SMT nozzle surface 1 are bent downward and then approach each other to form an elastic clamp 3 corresponding to the insertion hole 2. The elastic clamp 3 is configured to clamp the wire 20. Two second opposing sides of the SMT nozzle surface 1 are bent downward to form weld legs 4. The weld legs 4 are electrically connected to a printed circuit board 30.

For the wire 20 to be inserted into the elastic clamp 3 conveniently, the two first opposing sides of the SMT nozzle surface 1 are bent downward and inclined inwardly so that the lower ends of the two first opposing sides approach each other to form the elastic clamp 3 having oblique surfaces for guiding the wire 20 to be inserted therein. The elastic clamp 3 at the lower ends of the two first opposing sides of the SMT nozzle surface 1 is formed with a pair of clamping recesses 5 corresponding to the insertion hole 2.

In order to facilitate the electrical connection with the printed circuit board 30, the two second opposing sides of the SMT nozzle surface 1 are bent downward and then horizontally bent outward to form the weld legs 4. Specifically, the lower ends of the two second opposing sides of the SMT nozzle surface 1 are formed with the weld legs 4, respectively.

In order to simplify the structure and facilitate molding, the female connector 10 of the present invention is formed by stamping a metal sheet.

The structure of the present invention is simple. When the female connector 10 is to be assembled, the SMT nozzle surface 1 is sucked by the SMT nozzle, and the female connector 10 is arranged at a proper position of the printed circuit board 30, and then the weld legs 4 are soldered on the printed circuit board 30 to complete the assembly. The printed circuit board 30 does not need to be provided with an insertion hole, which omits the operation of aligning the elastic clamp 3 with the insertion hole. The assembly operation is simpler and more convenient. The required assembly area is small, the required operation space is small, and the printed circuit board 30 is also small. The female connector of the present invention is suitable for the electrical connection of small-sized products.

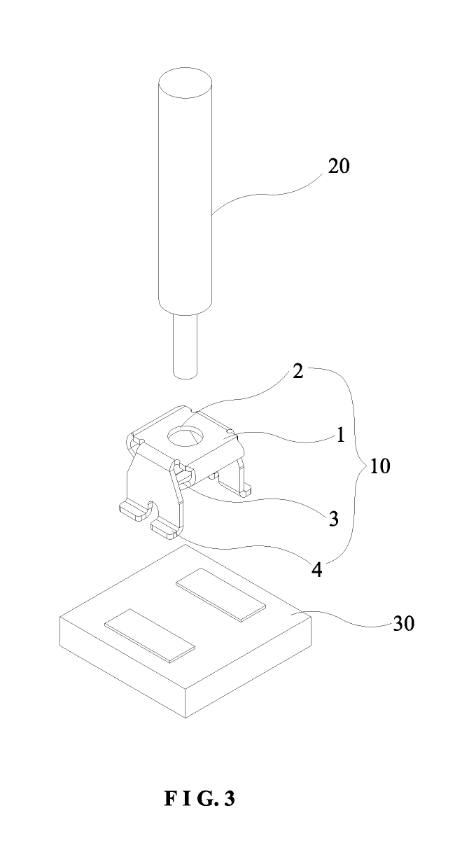

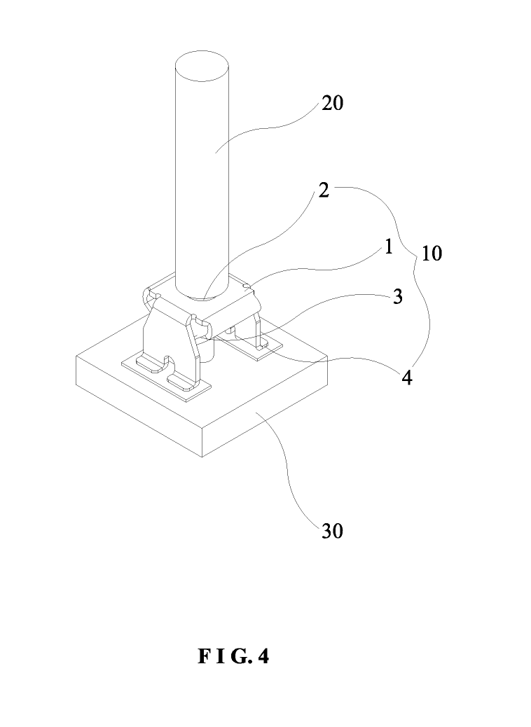

The present invention also discloses a connecting structure using the aforesaid all-metal surface mount female connector for plugging a wire from top to bottom. As shown in FIG. 3 and FIG. 4, the weld legs 4 of the female connector 10 are soldered on the printed circuit board 30. The wire 20 passes through the insertion hole 2 from top to bottom. The elastic clamp 3 is configured to clamp the wire 20 tightly, so that the electrical connection between the wire 20 and the printed circuit board 30 is achieved. The electrical connection way is simple, and the electrical connection is firm and stable.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. An all-metal surface mount female connector, having a SMT (surface mount technology) nozzle surface, the SMT nozzle surface being formed with an insertion hole for a wire to pass through the insertion hole from top to bottom, two first opposing sides of the SMT nozzle surface being bent downward and approaching each other to form an elastic clamp corresponding to the insertion hole for insertion of the wire, two second opposing sides of the SMT nozzle surface being bent downward to form weld legs, the weld legs being electrically connected to a printed circuit board.

2. The all-metal surface mount female connector as claimed in claim 1, wherein the two first opposing sides of the SMT nozzle surface are bent downward and inclined inwardly so that lower ends of the two first opposing sides approach each other to form the elastic clamp having oblique surfaces for guiding the wire to be inserted therein.

3. The all-metal surface mount female connector as claimed in claim 1, wherein lower ends of the two first opposing sides of the SMT nozzle surface are formed with a pair of clamping recesses corresponding to the insertion hole.

4. The all-metal surface mount female connector as claimed in claim 1, wherein the two second opposing sides of the SMT nozzle surface are bent downward and then horizontally bent outward to form the weld legs.

5. The all-metal surface mount female connector as claimed in claim 1, wherein lower ends of the two second opposing sides of the SMT nozzle surface are formed with the weld legs, respectively.

6. The all-metal surface mount female connector as claimed in claim 1, wherein the all-metal surface mount female connector is formed by stamping a metal sheet.

7. A connecting structure using the all-metal surface mount female connector as claimed in claim 1, wherein the weld legs of the all-metal surface mount female connector are soldered on the printed circuit board, the wire passes through the insertion hole from top to bottom, the elastic clamp is configured to clamp the wire tightly to achieve an electrical connection between the wire and the printed circuit board.
